(19) United States
(12) Patent Application Publication
(10) Pub. No.: US 2012/0178200 A1
(43) Pub. Date: Jul. 12, 2012

(54) INTEGRATED IN-LINE PROCESSING SYSTEM FOR SELECTIVE EMITTER SOLAR CELLS

(75) Inventor: MICHAEL P. STEWART, San Francisco, CA (US)

(73) Assignee: APPLIED MATERIALS, INC., Santa Clara, CA (US)

(21) Appl. No.: 13/325,816

(22) Filed: Dec. 14, 2011

Related U.S. Application Data
(60) Provisional application No. 61/431,299, filed on Jan. 10, 2011.

(51) Int. Cl. H01L 31/18; B05C 5/00; C23C 16/48

(52) U.S. Cl. 438/57; 118/723 R; 118/620; 257/E31.001

(57) ABSTRACT

Embodiments of the present invention are directed to an in-line system and process for forming a selective emitter solar cell. In one embodiment, a liquid dopant material is applied to a silicon substrate and dried to at least a semi-solid state. In another embodiment, a dopant material is deposited on a silicon substrate using a chemical vapor deposition process. A laser is then used to thermally excite regions of the substrate to drive the dopant atoms from the dopant material deep into the substrate to form highly doped regions. The substrate is then thermally processed to form a lightly doped emitter region and a shallow p-n junction in the remaining field region of the substrate. Conductive contacts are then deposited on the highly doped regions.

### CROSS-REFERENCE TO RELATED APPLICATIONS

This application claims benefit of U.S. provisional patent application Ser. No. 61/431,299, filed Jan. 10, 2011, which is herein incorporated by reference.

### BACKGROUND OF THE INVENTION

1. Field of the Invention

Embodiments of the present invention generally relate to a system and process for forming selective emitter solar cells.

2. Description of the Related Art

Solar cells are photovoltaic (PV) devices that convert sunlight into electrical power. A typical solar cell includes a silicon substrate, or wafer, that is less than about 0.3 mm thick with one or more p-n junctions formed therein. Each p-n junction has a p-type region and an n-type region. When the p-n junction is exposed to sunlight, the sunlight is converted to electricity through the PV effect. Solar cells generate a specific amount of electric power and are tiled into modules sized to deliver a desired amount of system power.

FIGS. 1A and 1B schematically depict a solar cell 10 fabricated on a silicon substrate 11. The substrate 11 includes a p-type base region 21, an n-type emitter region 22, and a p-n junction region 23 disposed therebetween. The n-type emitter region 22 is formed by doping the substrate 11 with certain types of elements (e.g., phosphorus (P), arsenic (As), or antimony (Sb)) in order to increase the number of negative charge carriers, i.e., electrons. Similarly, the p-type base region 21 is formed by the addition of trivalent dopant atoms to the crystal lattice, resulting in a missing electron from one of the four covalent bonds normal for the silicon lattice. The dopant atom accepts an electron, causing the loss of half of one bond from the neighboring atom, resulting in the formation of a “hole.”

When the solar cell 10 is exposed to light, energy from incident photons generates electron-hole pairs on both sides of the p-n junction region 23. Electrons and holes diffuse in opposite directions creating a negative charge in the n-type emitter region 22 and a corresponding positive charge in the p-type base region 21. Current flows when an electrical circuit is made between the n-type emitter region 22 and the p-type base regions 21 as the p-n junction is exposed to certain wavelengths of light. The electrical current generated flows through conductive contacts, or fingers 14, disposed on the front side 18, i.e., the light receiving side, and a back contact 25 on the back side 19 of the solar cell 10. The fingers 14 supply the current to a larger bus bar 15. The solar cell 10 is generally covered with a thin layer of dielectric material to act as an anti-reflection coating 16 to minimize light reflection from a top surface 50 of the solar cell 10.

To enhance the contact with the solar cell 10, the fingers 14 are positioned on heavily doped regions 17 formed within the substrate surface to enable low resistance contact with the n-type emitter region 22. Due to their electrical properties, the heavily doped regions 17 tend to block or minimize the amount of light that can pass therethrough. Therefore, it is desirable to minimize the size of the heavily doped regions 17, while ensuring that these regions are large enough to reliably form the fingers 14 thereon.

The heavily doped regions 17 may be formed on the substrate surface using a variety of patterning techniques to create areas of heavier doping. One example of forming the heavily doped regions 17 includes using a batch processing system to bubble nitrogen gas through liquid phosphorus oxychloride (POCl₃) sources, which are injected into an enclosed quartz furnace loaded with batch-type quartz boats containing substrates with masked regions. However, such batch processing requires a number of substrate transfer and handling steps, which results in increased chances of substrate damage or breakage. Another example of forming the heavily doped regions 17 includes using an in-line system to coat phosphosilicate glass compounds onto the surface of the substrates and performing diffusion annealing to drive the dopant atoms into the substrate. The substrates are then taken off-line to drive dopant atoms deep into the silicon to form the heavily doped regions. However, removing the substrates from the in-line system to perform the laser processes also requires additional handling steps, which result in increased chances of substrate damage or breakage. In addition, the laser processing is performed on atoms that are already diffused into the substrate, resulting in inefficient and low quality diffusion in the heavily doped regions.

Therefore, there is a need for improved apparatus and processes for forming selective emitter solar cells.

### SUMMARY OF THE INVENTION

In one embodiment, a method of forming a solar cell comprises applying a dopant material layer onto a substrate, laser scanning a pattern on the dopant material layer to diffuse dopant atoms into the substrate to create a pattern of heavily doped regions in the substrate, and thermally processing the substrate after laser scanning the pattern to form an emitter field region in the substrate.

In another embodiment, a method of forming a solar cell comprises applying a dopant material layer on one or more surfaces of a silicon substrate, laser scanning a pattern on the dopant material layer to diffuse dopant atoms into the substrate to create a pattern of heavily doped regions in the substrate, thermally processing the substrate after laser scanning the pattern to form an emitter field region in the substrate, and depositing one or more conductive contacts onto the heavily doped regions. The heavily doped regions have a sheet resistance of less than about 50 ohms/square.

In yet another embodiment, an in-line system for forming a solar cell comprises a doping module configured to apply a layer of dopant material to one or more surfaces of a substrate, a laser scanning module positioned downstream from the doping module and having a laser configured to scan a pattern on the dopant material to diffuse the atoms into the substrate to create a pattern of heavily doped regions in the substrate, and a thermal processing module positioned downstream from the laser scanning module and configured to heat the substrate to greater than 800 degrees Celsius to form an emitter field region in the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is an isometric view of a prior art selective emitter solar cell.

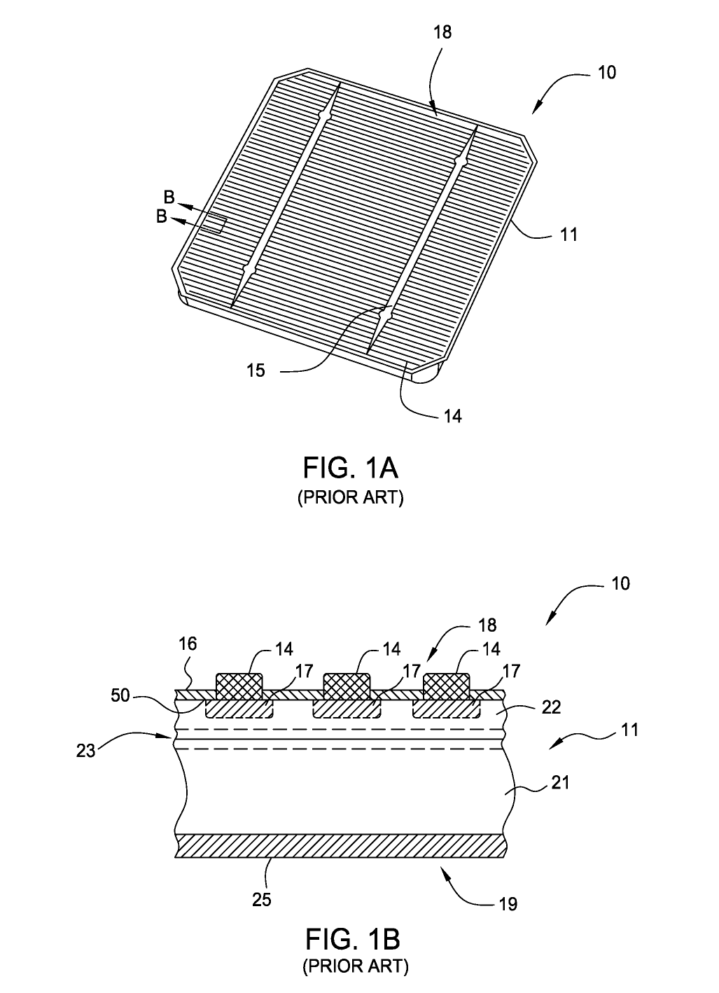

FIG. 1B is a cross-sectional side view of the prior art solar cell shown in FIG. 1A taken along line B-B.

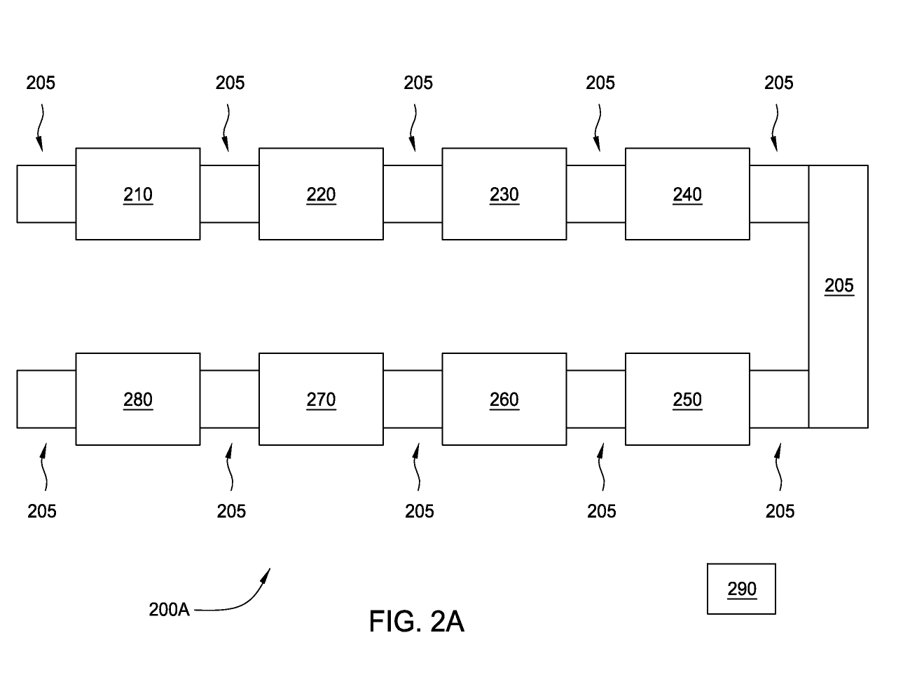

FIG. 2A is a schematic, plan view of an in-line processing system according to one embodiment.

FIG. 2B is a schematic, cross-sectional view of an in-line processing system according to another embodiment.

FIGS. 3A-3G are schematic, cross-sectional views of a solar cell substrate during different stages of a processing sequence used to form a selective emitter solar cell using an in-line system according to one embodiment.

FIG. 4A is a block diagram of a processing sequence used to form a selective emitter solar cell in an in-line system according to one embodiment.

FIG. 4B is a block diagram of a processing sequence used to form a selective emitter solar cell in an in-line system according to another embodiment.

### DETAILED DESCRIPTION

Embodiments of the present invention are directed to an in-line system and process for forming a selective emitter solar cell. In one embodiment, a liquid dopant material is applied to a silicon substrate and dried to at least a semi-solid state. In another embodiment, a dopant material is deposited on a silicon substrate using a chemical vapor deposition process. A laser is then used to thermally excite regions of the substrate to drive the dopant atoms from the dopant material deep into the substrate to form highly doped regions. The substrate is then thermally processed to form a lightly doped emitter region and a shallow p-n junction in the remaining field region of the substrate. Conductive contacts are then deposited on the highly doped regions. The field region of the resulting solar cell has a highly resistive emitter region that absorbs minimal light so that an increased amount of light reaches the p-n junction for conversion into electrical current. The highly doped regions of the resulting solar cell have very low electrical resistance to provide a highly conductive path between the emitter region and the conductive contacts.

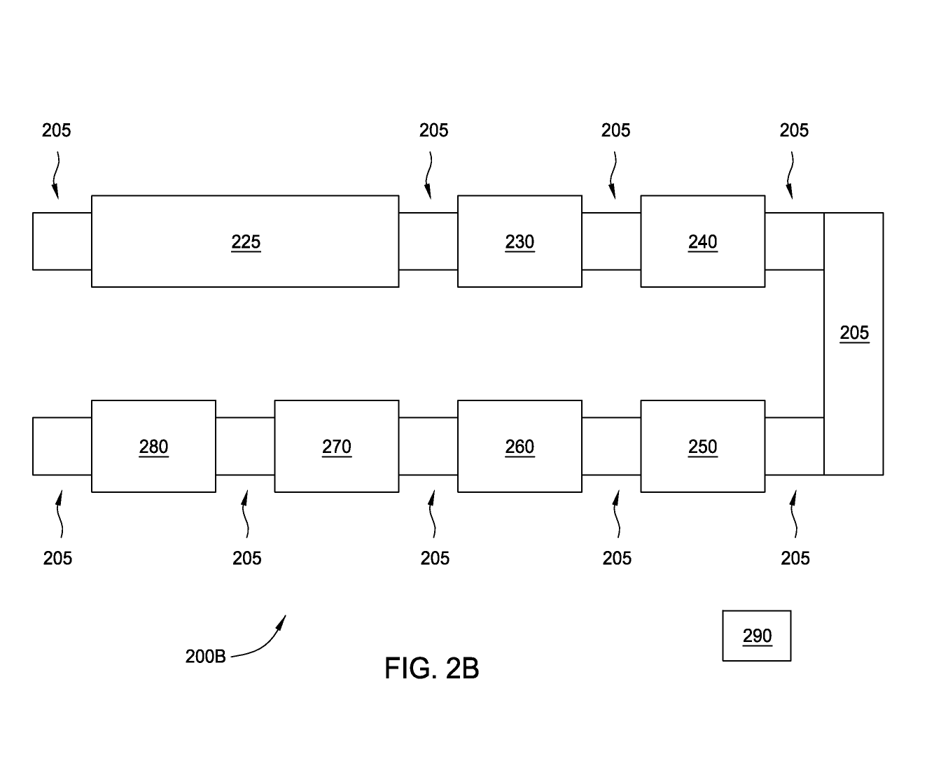

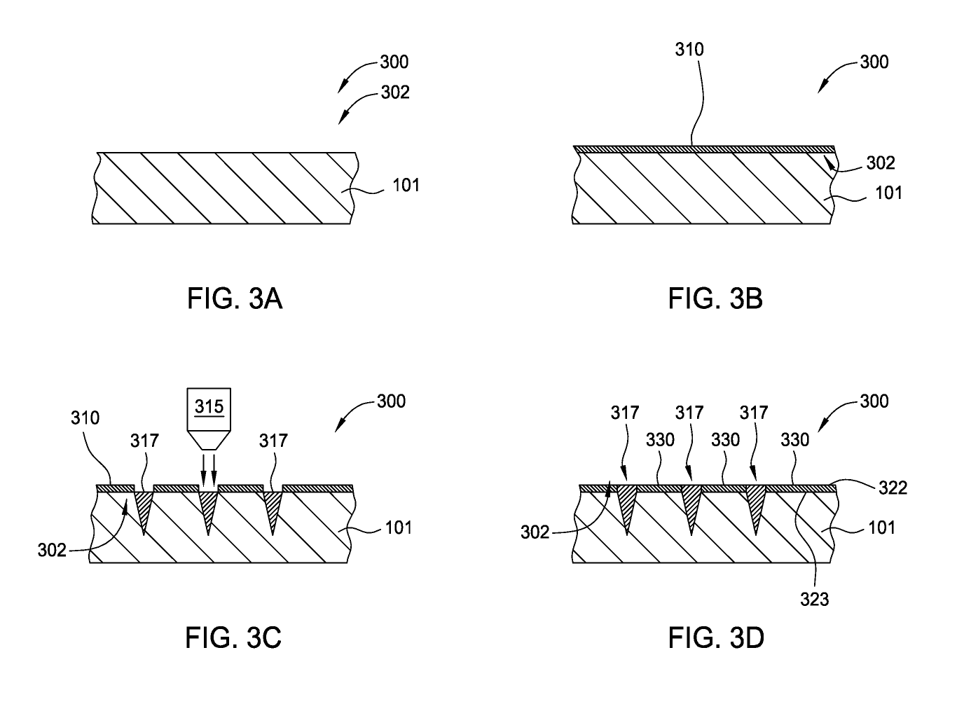

FIG. 2A is a schematic, plan view of an in-line processing system 200A according to one embodiment. The in-line processing system 200A includes a first cleaning chamber 210, a dopant application chamber 220, a drying chamber 230, a laser doping chamber 240, a thermal processing chamber 250, a second cleaning chamber 260, a deposition chamber 270, a metal formation chamber 280, and a system controller 290.

FIG. 2B is a schematic, cross-sectional view of an in-line processing system 200B according to another embodiment. The in-line processing system 200B is substantially the same as the processing system 200A except a deposition chamber 225 replaces the dopant application chamber 220 and the drying chamber 230.

In both the processing system 200A and 200B, substrates 101 are supported and transferred through the in-line processing system 200A, 200B on one or more conveying mechanisms 205. The conveying mechanisms 205 may include a plurality of conveyor belts driven by actuators, such as one or more motors.

The system controller 290 facilitates the control and automation of the overall system 200A, 200B and may include a central processing unit (CPU) (not shown), memory (not shown), and support circuits (not shown). The CPU may be one of any form of computer processors that are used in industrial settings for controlling various chamber processes and hardware (e.g., conveyors, motors, fluid delivery hardware, laser hardware, thermal processing hardware, cleaning hardware) and monitor the system and chamber processes (e.g., substrate position, process time). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, and the like. A program (or computer instructions) readable by the system controller 290 determines which tasks are performable on a substrate 101. Preferably, the program is software readable by the system controller 290, which includes code to generate and store at least substrate positional information, the sequence of movement of the various controlled components, laser processing information, thermal processing information, and any combination thereof.

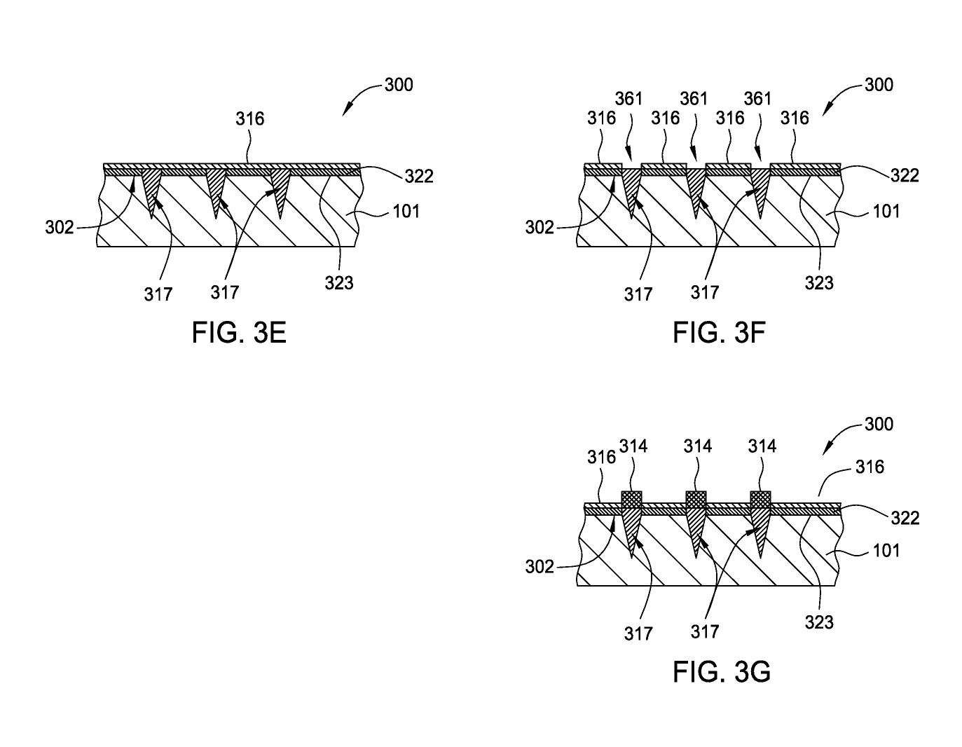

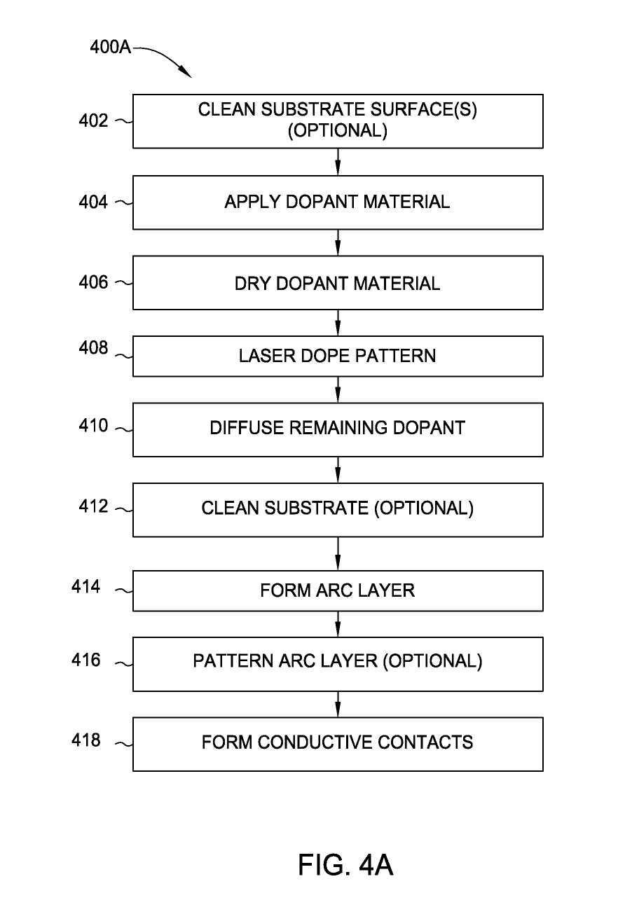

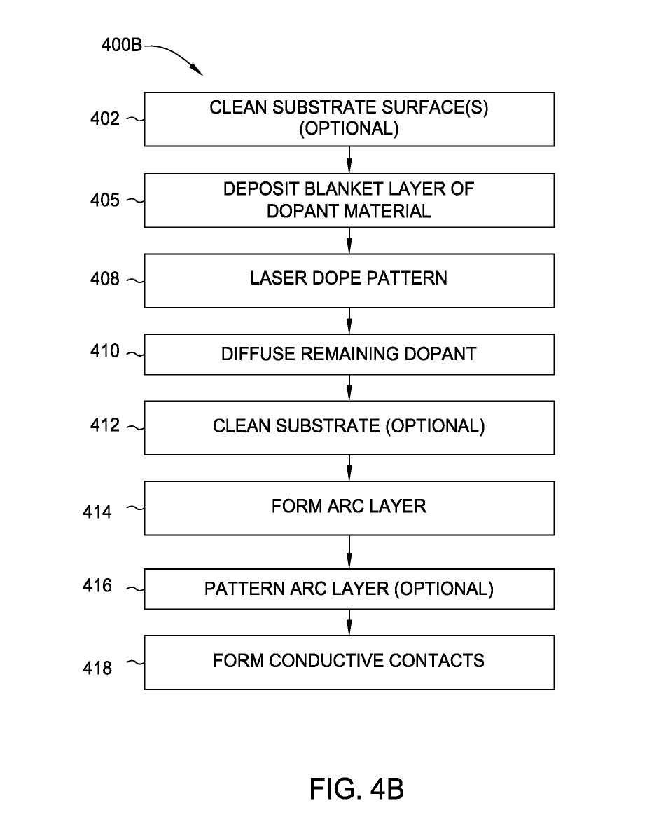

FIGS. 3A-3G are schematic, cross-sectional views of a solar cell substrate 101 during different stages of a processing sequence used to form a solar cell 300 using the in-line system 200A or 200B. FIG. 4A is a block diagram illustrating a process sequence 400A used to form the solar cell 300 using the system 200A.

At box 402, and as shown in FIGS. 2A, 3A, and 4A, surfaces of the substrate 101 may first be cleaned in the first cleaning chamber 210 to remove any undesirable material or roughness. The substrates 101 may be cleaned using a wet cleaning process in which they are sprayed with cleaning solution. The cleaning solution may be a conventional SC1 cleaning solution, SC2 cleaning solution, HF-last type cleaning solution, ozonated water cleaning solution, hydrofluoric acid (HF) and hydrogen peroxide (H₂O₂) solution, or other suitable cleaning solution. The cleaning process may be performed on the substrate 101 between about 5 seconds and about 600 seconds, such as about 120 seconds. Alternatively, the cleaning process may include a two step process in which a saw damage removal step is first performed on the substrate 101, and then a second cleaning step is performed. The saw damage removal step may include exposing the substrate 101 to an aqueous solution having potassium hydroxide (KOH) that is maintained at about 70 degrees Celsius.

At box 404, a dopant material 310 is applied to one or more surfaces of the substrate 101 in the dopant application chamber 220. The dopant material 310 may be applied to one or both sides of the substrate 101. FIG. 2B depicts the dopant material applied to only an upper surface 302 of the substrate 101. In one embodiment, the substrate 101 is a p-type substrate, and the dopant material 310 is an n-type dopant material, such as a phosphorus based acid (HPOₓ) (e.g., H₃PO₄, H₃PO₃, H₃PO₂). In another embodiment, the substrate 101 is an n-type substrate, and the dopant material 310 is a p-type dopant material, such as boric acid (H₃BO₃). In either embodiment, the dopant material 310 is a liquid material that may be sprayed on using one or more nozzles or rolled on using one or more sponge rollers or the like.

At box 406, the substrate 101 is processed in the drying chamber 230. In the drying chamber 230, the substrate 101 is processed at a temperature between about 50 degrees Celsius and about 350 degrees Celsius in order to dry the dopant material 310 into a uniform and more solid state. The temperature of the drying chamber 230 is controlled to be high enough that the dopant material 310 is dried into at least a “tacky” state, but low enough that the dopant atoms in the dopant material are not diffused into the silicon substrate 101.

At box 408, as shown in FIGS. 3C and 4A, a scanning laser 315 within the laser doping chamber 240 is used to form heavily doped regions 317 in the substrate 101. In one example, the scanning laser 315 thermally excites a grid pattern on the dried dopant material 310. The grid pattern excited by the scanning laser 315 includes about 6% to 10% of the total surface area of the dopant material 310, and thus substrate surface 302. In the areas where the laser excites the surface of the dopant material 310 and substrate 101, dopant atoms in the dopant material 310 are rapidly driven deep into the silicon substrate 101. The result is a grid pattern of heavily doped regions 317 having very low sheet resistance (Rs). In one example, the heavily doped regions 317 have a doping level greater than about 10¹⁸ atoms/cm³. The sheet resistance of the heavily doped regions 317 is generally less than about 50 Ohms per square (Ω/□). In one example, the sheet resistance of the heavily doped regions 317 is between about 10Ω/□ and about 30Ω/□. Thus, the heavily doped regions 317 provide an extremely low resistant path between a p-n junction subsequently formed in the substrate 101 and conductive contacts subsequently formed on the heavily doped regions 317. In one example, the scanning laser 315 also thermally excites one or more regions of the substrate 101 to create fiducial marks thereon for use in subsequently alignment for depositing the conductive contacts on the heavily doped regions 317 of the substrate 101.

The scanning laser 315 may be any laser that is capable of providing sufficient power to heat the dopant material 310 and substrate 101 without damaging the substrate 101. Some examples of lasers that are capable of accomplishing this are neodymium doped YAG lasers, neodymium doped YBO₄ solid state lasers, or Yb doped glass fiber lasers, which can be operated in a pulsed mode with the desired beam parameters.

At box 410, as shown in FIGS. 3D and 4A, the substrate 101 is heated to a temperature greater than about 800 degrees Celsius in the thermal processing chamber 250. In one example, the substrate 101 is heated to a temperature between about 800 degrees Celsius and about 1300 degrees Celsius in the presence of nitrogen (N₂), oxygen (O₂), hydrogen (H₂), air, or combinations thereof for between about 1 minute and about 120 minutes. The substrate 101 may be heated in a nitrogen (N₂) rich environment in a rapid thermal annealing (RTA) chamber to a temperature of about 1000 degrees Celsius for about 5 minutes. One example of an inline system that may be modified to accomplish the thermal processing step is the ATON system manufactured by Applied Materials, Inc. of Santa Clara, Calif. The thermal processing of the substrate 101 causes the doping atoms in the undiffused regions of the dopant material 310 to diffuse into the surface of the substrate 101 to form a lightly doped emitter region 322 and a shallow p-n junction 323 in the previously undiffused, or field area 330, of the surface of the substrate 101. In one example, the field area 330 includes between about 90% and about 94% of the surface area of the substrate 101. After diffusion in the thermal processing chamber 250, the field area 330 of the substrate 101 has a sheet resistance of greater than about 50Ω/□, such as between about 50Ω/□ and about 100Ω/□. Thus, after diffusion in the thermal processing chamber 250, the substrate 101 has a grid pattern of heavily doped regions 317 where the sheet resistance is very low and a field area 330 containing the high resistance emitter region 322. The high resistance emitter region 322 absorbs minimal light so that a maximum amount of light is transmitted to the p-n junction 323. At the same time, the low resistance, heavily doped regions 317 provide low resistance contact areas for subsequently deposited conductive contacts.

At box 412, an optional cleaning process is performed on the substrate 101 in the second cleaning chamber 260 after the processes performed in box 410 are completed to remove any undesirable residue and/or form a passivated surface on the substrate 101. In one example, the clean process may be performed by wetting surfaces of the substrate 101 with a cleaning solution. The clean process may be performed by wetting the substrate with a cleaning solution, such as an SC1 cleaning solution, an SC2 cleaning solution, HF-last type cleaning solution, ozonated water solution, hydrofluoric acid (HF) and hydrogen peroxide (H₂O₂) solution, or other suitable cleaning solutions. The clean process may be performed on the substrate 101 between about 5 seconds and about 600 seconds, such as about 30 seconds to about 240 seconds.

At box 414, as shown in FIGS. 3E and 4A, an antireflection layer 316 is formed on the surface 302 of the substrate 101 in the deposition chamber 270. The antireflection layer 316 may be a thin passivation/antireflection layer, such as silicon oxide or silicon nitride, for example. In one example, the antireflection layer 316 may also include a transparent conductive oxide (TCO) layer. The antireflection layer 316 may be deposited in the deposition chamber 270 using a physical vapor deposition (PVD) process or a chemical vapor deposition (CVD) process.

At box 416, as shown in FIGS. 3F and 4A, portions of the antireflection layer 316 are optionally etched to expose regions 361 of the heavily doped regions 317 so that subsequently deposited conductive contacts can be placed in intimate contact with the heavily doped regions 317. Thus, the etched pattern matches the pattern used to form the heavily doped regions 317. Typical etching processes that may be used to pattern the antireflection layer 316 may include patterning and dry etching techniques, laser ablation techniques, patterning and wet etching techniques, or other similar processes.

At box 418, as shown in FIGS. 3G and 4A, a conductive contact 314 is deposited in a pattern on the heavily doped regions 317 on the substrate 101 in the deposition chamber 270. The conductive contact 314 may be between about 500 angstroms and about 50,000 angstroms thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the conductive contact 314 is a metal paste that contains silver or tin and is deposited in a pattern matching the pattern used to form the heavily doped regions 317 using screen printing process performed by a Softline™ tool available from Baccini S.p.A, a division of Applied materials, Inc. of Santa Clara, Calif.

At box 416, heat is delivered to the conductive contact 314 to cause the metal in the conductive contact 314 to form an electrical connection to the heavily doped regions 317. The heating process may be performed in a heating oven within the deposition chamber 270.

FIG. 4B is a block diagram illustrating a process sequence 400B used to form the solar cell 300 using the system 200B. In general, the processes described above in conjunction with FIG. 4A are the same as those in the process sequence 400B, except that the processes in boxes 404 and 406 of process sequence 400A are replaced with a deposition process in box 405 as described below.

After performing the cleaning processes associated with box 402, the dopant material 310 is deposited on the substrate 101 using a deposition process, such as a plasma enhanced chemical vapor deposition (PECVD) process in the deposition chamber 225 shown in FIG. 2B. In box 405, a mixture of precursors, including one or more silicon containing precursors and one or more dopant precursors is delivered into the deposition chamber 225. In one example, the silicon containing precursors may include silane (SiH₄), disilane (Si₂H₆), tetrafluorosilane (SiF₄), or other silicon containing compounds useful for depositing a layer of amorphous silicon onto the substrate 101. In one example, the silicon containing compound is delivered at a flow rate of about 10 sccm or higher, such as between about 50 sccm and about 500 sccm.

In one embodiment, the substrate 101 is a p-type silicon substrate, and the dopant precursor is an n-type precursor. The n-type precursor may be a phosphorous containing compound, such as phosphine (PH₃). The phosphorous containing compound may be delivered at a concentration of 0.5% in hydrogen at a flow rate of about 30 sccm or higher, such as between about 150 sccm and about 1500 sccm. As a result, the dopant material 310 deposited on the substrate 101 is a blanket of n-type dopant material.

In another embodiment, the substrate 101 is an n-type silicon substrate, and the dopant precursor is a p-type precursor. The p-type precursor may be a boron containing compound. As a result, the dopant material 310 deposited on the substrate 101 is a blanket of p-type dopant material.

The remaining processes in boxes 408-418 of FIG. 4B are substantially the same as those depicted in and described with respect to FIG. 4A.

Thus, embodiments described herein are directed to an in-line system and process for forming a selective emitter solar cell. In one embodiment, a liquid dopant material is applied to a silicon substrate and dried to at least a semi-solid state. In another embodiment, a dopant material is deposited on a silicon substrate using a chemical vapor deposition process. A laser is then used to thermally excite regions of the substrate to drive the dopant atoms from the dopant material deep into the substrate to form highly doped regions. The substrate is then thermally processed to form a lightly doped emitter region and a shallow p-n junction in the remaining field region of the substrate. Conductive contacts are then deposited on the highly doped regions. The field region of the resulting solar cell has a highly resistive emitter region that absorbs minimal light so that an increased amount of light reaches the p-n junction for conversion into electrical current. The highly doped regions of the resulting solar cell have very low electrical resistance to provide a highly conductive path between the emitter region and the conductive contacts.

Embodiments described herein have a number of advantages over prior art systems and processes. As one example, the in-line system of the present invention provides a fabrication process with minimal handling as compared to prior art batch systems that require picking, placing and buffering of substrates. Thus, the system and process of the present invention significantly decreases the chances of substrate damage or breakage as compared to the prior art batch processing systems. As another example, the in-line system of the present invention provides formation of highly doped regions prior to any diffusion of the dopant atoms into the silicon substrate material. In contrast, prior art systems first diffuse dopant material into the substrate to create the p-n junction and then drive the already diffused atoms deeper into the substrate to form the highly doped regions. It is believed that the use of a fresh, undiffused dopant source, as in the present invention, results in greater diffusion quality and ultimately in lower resistant highly doped regions for greater conductive contact with the conductive contacts than is achievable with prior art systems.

While the foregoing is directed to embodiments of the present invention, other and further embodiments of the invention may be devised without departing from the basic scope thereof, and the scope thereof is determined by the claims that follow.

1. A method of forming a solar cell, comprising:
applying a dopant material layer onto a substrate;
laser scanning a pattern on the dopant material layer to diffuse dopant atoms into the substrate to create a pattern of heavily doped regions in the substrate; and
thermally processing the substrate after laser scanning the pattern to form an emitter field region in the substrate.

2. The method of claim 1, wherein applying the dopant comprises applying liquid dopant to at least one surface of the substrate.

3. The method of claim 2, wherein the dopant is applied by spraying.

4. The method of claim 2, wherein the dopant is applied by rolling.

5. The method of claim 2, further comprising drying the dopant prior to laser scanning the pattern.

6. The method of claim 5, wherein the dopant is dried at a temperature between about 50 degrees Celsius and about 350 degrees Celsius.

7. The method of claim 1, wherein applying the dopant comprises depositing a blanket of dopant material onto one or more surfaces of the substrate.

8. The method of claim 1, wherein the pattern of heavily doped regions comprises between about 6% and about 10% of the surface of the substrate.

9. The method of claim 8, wherein the heavily doped regions have a sheet resistance between about 10 ohms/square and about 30 ohms/square.

10. The method of claim 9, wherein the emitter field region has a sheet resistance between about 50 ohms/square and about 100 ohms/square.

11. The method of claim 8, wherein thermally processing comprises heating the substrate between about 800 degrees Celsius and about 1300 degrees Celsius.

12. A method of forming a solar cell, comprising:
applying a dopant material layer on one or more surfaces of a substrate;
laser scanning a pattern on the dopant material layer to diffuse dopant atoms into the substrate to create a pattern of heavily doped regions in the substrate, wherein the heavily doped regions have a sheet resistance of less than about 50 ohms/square;
thermally processing the substrate after laser scanning the pattern to form an emitter field region in the substrate; and
depositing one or more conductive contacts onto the heavily doped regions.

13. The method of claim 12, wherein the heavily doped regions comprise between about 6% and about 10% of the surface area of the substrate.

14. The method of claim 12, wherein applying the dopant material comprises applying a liquid dopant.

15. The method of claim 14, further comprising drying the dopant material prior to laser scanning the pattern.

16. The method of claim 12, wherein applying the dopant material comprises depositing a blanket layer of dopant.

17. The method of claim 12, wherein the emitter field region has a sheet resistance of greater than about 50 ohms/square.

18. An in-line system for forming a solar cell, comprising:
a doping module configured to apply a layer of dopant material to one or more surfaces of a substrate;
a laser scanning module positioned downstream from the doping module and having a laser configured to scan a pattern on the dopant material to diffuse the atoms into the substrate to create a pattern of heavily doped regions in the substrate; and
a thermal processing module positioned downstream from the laser scanning module and configured to heat the substrate to greater than 800 degrees Celsius to form an emitter field region in the substrate.

19. The in-line system of claim 18, wherein the doping module is configured to apply a liquid dopant to the substrate, and further comprising a drying module downstream from the doping module configured to dry the liquid dopant.

20. The in-line system of claim 18, wherein the doping module is a chemical vapor deposition module configured to apply a blanket dopant layer to the substrate.
